(19) United States
(12) Patent Application Publication
(10) Pub. No.: US 2026/0090303 A1
(43) Pub. Date: Mar. 26, 2026

(54) POST ETCH PLASMA TREATMENT FOR REDUCING SIDEWALL CONTAMINANTS AND ROUGHNESS

(71) Applicant: Lam Research Corporation, Fremont, CA (US)

(72) Inventors: Daksh AGARWAL, Sunnyvale, CA (US); Taner OZEL, Fremont, CA (US); Amit MUKHOPADHYAY, Fremont, CA (US); Qing XU, Fremont, CA (US); Merrett WONG, Palo Alto, CA (US)

(21) Appl. No.: 19/111,984

(22) PCT Filed: Sep. 26, 2023
(86) PCT No.: PCT/US2023/075090

§ 371 Date: Mar. 14, 2025

Related U.S. Application Data
(60) Provisional application No. 63/411,331, filed on Sep. 29, 2022.

(51) Int. Cl. H10P 50/26; H01J 37/32

(52) U.S. Cl. CPC H10P 50/268; H01J 37/3244; H10P 50/283; H10P 70/23; H10P 70/27; H01J 2237/335

(57) ABSTRACT

A method of forming features in stack with a silicon containing layer below a mask is provided. Features are etched into the stack. A post etch plasma treatment is provided to reduce surface roughness of sidewalls of the features.

### CROSS-REFERENCE TO RELATED APPLICATION

This application claims the benefit of priority of U.S. Application No. 63/411,331, filed Sep. 29, 2022, which is incorporated herein by reference for all purposes.

### BACKGROUND

In forming semiconductor devices, etch layers may be etched to form memory holes or lines or other semiconductor features. Some semiconductor devices may be formed by etching a single stack of silicon dioxide also known as silicon oxide (SiO₂), for example, to form a capacitor in dynamic access random memory (DRAM). Other semiconductor devices may be formed by etching stacks of bilayers of alternating silicon dioxide (oxide) and silicon nitride (nitride) (ONON), or alternating silicon dioxide and polysilicon (OPOP). Other stacks of alternating layers may be etched. Some of the stacks of alternating layers may have one of the layers of the alternating layers that is silicon oxide. Some alternating layers may be alternating trilayers. Such stacks may be used in memory applications and three dimensional “not and” gates (3D NAND). These stacks tend to require relatively high aspect ratio (HAR) etching of the dielectrics. For high aspect ratio etches, examples of desired etch characteristics are high etch selectivity to the mask (such as an amorphous carbon mask), low sidewall etching with straight profiles, and high etch rate at the etch front. Some high aspect ratio etches result in tapered features that are much wider at the top than the bottom. Such features may increase device failure or limit device density, device performance, and device depth.

In some etch processes of an OPOP stack with an amorphous carbon mask, during the etch, a metal containing passivant is used during the etch process. The metal containing passivant may be provided during the etch process so that passivation and etching occur simultaneously or there may be alternating steps of passivation and etching.

The background description provided here is for the purpose of generally presenting the context of the disclosure. The information described in this background section, as well as aspects of the description that may not otherwise qualify as prior art at the time of filing, are neither expressly nor impliedly admitted as prior art against the present disclosure.

### SUMMARY

To achieve the foregoing and in accordance with the purpose of the present disclosure, a method for etching features in a stack comprising a silicon oxide layer below a mask is provided. A substrate support for supporting the stack in an etch chamber is cooled to a temperature below 0° C. An etch gas comprising a halogen containing component and a phosphorous containing component is provided. A plasma is generated from the etch gas. A bias is provided to accelerate ions from the plasma to the stack. Features are selectively etched in the stack with respect to the mask.

In another manifestation, an apparatus for processing a stack over a substrate with at least one of a silicon oxide layer and silicon nitride layer below a mask is provided. An etch chamber is provided. A substrate support supports a substrate inside the etch chamber. A temperature controller controls a temperature of the substrate support. An electrode provides RF power inside the etch chamber. An RF power source provides RF power to the electrode. A gas source provides an etch gas into the etch chamber where the gas source comprises a halogen containing component source and an HF gas source.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 depicts a flow chart describing a method of etching recessed features into a stack containing dielectric material according to various embodiments.

FIGS. 2A-E shows a stack processed according to some embodiments.

FIG. 3 illustrates a reaction chamber that may be used to perform the techniques described herein according to certain embodiments.

FIG. 4 illustrates a computer system for implementing a controller used in embodiments of the present inventions.

In the drawings, like reference numerals are sometimes used to designate like structural elements. It should also be appreciated that the depictions in the figures are diagrammatic and not to scale.

### DETAILED DESCRIPTION

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

Fabrication of certain semiconductor devices involves etching features into a stack of materials using plasma-based etch processes. In various embodiments herein, the stack of materials includes alternating/repeating layers of dielectric material. In a number of cases, at least one of the layers in the stack is or includes silicon containing layer. Silicon containing layers may contain silicon nitride, silicon oxide, silicon carbide, silicon oxy-nitride, silicon oxy-carbide, polysilicon, or silicon germanium. In one example, the stack includes alternating layers of silicon oxide and polysilicon. In some embodiments, the stack comprises an alternating silicon oxide film with silicon nitride films, or single silicon oxide layer, or single silicon layer.

The features etched into silicon containing materials may be cylinders, trenches, or other recessed features. The aspect ratio of such a feature is defined as the lateral critical dimension divided by the depth. As the aspect ratio of such features continues to increase, several issues arise including (1) twisting of the features, (2) non-circularity of the features, (3) aspect-ratio dependent etch rate, (4) bowing etch profile, (5) insufficient mask selectivity, and (6) low etch rate. Twisting refers to random deviations between the intended bottom locations of the features and the actual final bottom locations of the features (e.g., with the final location of a feature corresponding to the position of the bottom of the feature after the feature is etched). For instance, in some cases, it is intended that cylindrical features are etched in a regular array. When some or all features randomly deviate at the bottom away from this array, they are understood to have twisted.

Non-circularity of the features refers to deviations of the bottom hole shape away from a circular hole shape. This issue is relevant when etching circular features such as cylinders, where it is desired that the bottoms of the recessed features are circular. When the bottom hole shape deviates away from a circular shape, it often forms a shape closer to an ellipse, triangle, or irregular polygon. In many cases, these non-circular shapes are not desirable.

Aspect-ratio dependent etch rate refers to an issue where the etch rate slows down as the aspect ratio of the features increases. In other words, as the features are etched further into the dielectric material, the etching process slows down. This issue is problematic because it can lead to low throughput and associated high processing costs.

Bowing etch profile refers to the tendency for the features to etch laterally in the dielectric layer such that the final profile bows outwards excessively somewhere along the depth of the features. In other words, the actual maximum critical dimension of the features exceeds the desired maximum critical dimension of the features, which can compromise the integrity of the structures being formed or limit the electrical performance of the final devices.

Insufficient mask selectivity is problematic when the etch process removes an excessive amount of mask, such no mask remains at the end of the process, or that the amount of mask remaining is insufficient to properly transfer the pattern from the mask to the dielectric film(s). One common result of insufficient mask selectivity is the degradation of the feature profile near the top of the recessed features.

Low etch rate refers to an etch rate that is slower than desired for a particular application. Low etch rate is problematic because it leads to long etch times, reduced throughput, and high processing costs.

Unfortunately, techniques that improve some of these issues often make other issues worse. As such, these issues are balanced against one another when designing an etching operation. For example, conventional commercially practiced dielectric etch processes often result in substantial bowing. Low temperature etch processes have recently been developed to address the bowing problem associated with the conventional commercially practiced dielectric etch processes. Such low temperature processes may take place while the substrate support is cooled to a temperature of less than about 25° C. Advantageously, the low temperature processes also result in a relatively high etch rate and relatively low bowing. However, these low temperature processes substantially exacerbate issues related to twisting and non-circularity of the features. Previously, such tradeoffs have been difficult to avoid.

Dry development of high aspect ratio contacts requires strict control of the tapering angle of the sidewall. Various methods try to limit lateral critical dimension (CD) differences between the top and bottom parts of the etched structures. With the recent development of 3D NAND memory having thicker structures with an increased number of ONON or OPOP bilayers, the demand for tight control of top and bottom geometries is especially significant. In case the profile (difference between the top and bottom CDs) increases, subsequent steps of device manufacturing will be at risk that will impact device performance. In the current technology, reactive ion etching of high aspect ratio structures relies on sidewall deposition to protect against CD lateral erosion. A delicate balance between etching and sidewall deposition is especially difficult to maintain for high aspect ratio features. As a result, high aspect ratio dry development is limited to thinner structures and requires significant complex development to enable a thick stack to be etched.

As etched features become deeper and etch times increase, defects such as notching, mouse bites, and scalloping at interface layers increase sidewall surface roughness. Such an increase in surface roughness affects downstream processes, such as deposition, and is detrimental to device fabrication. Although passivation during the etch helps reduce surface roughness, the resulting surface roughness is still too high.

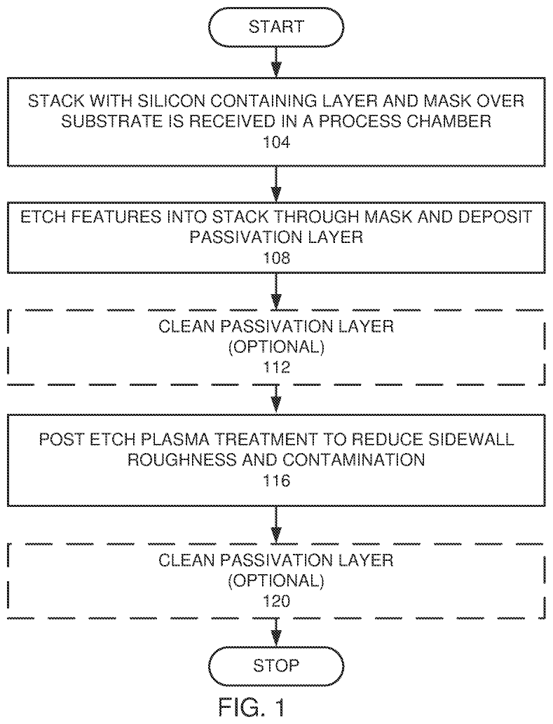

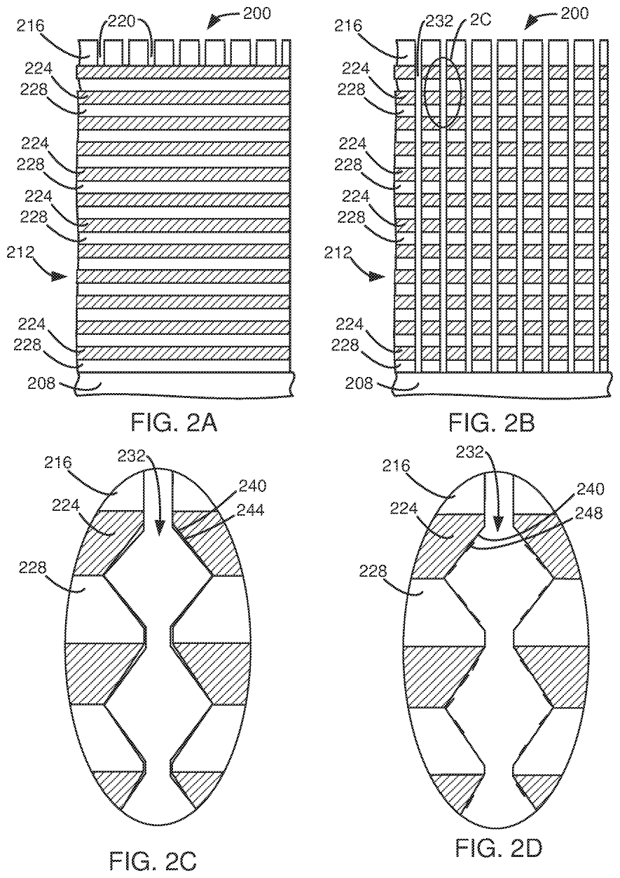

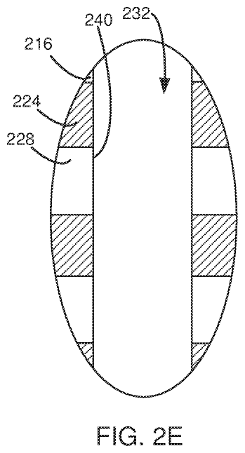

Embodiments described herein provide deeper high aspect ratio features etched in a stack with reduced sidewall roughness and contamination. To facilitate understanding, FIG. 1 is a high level flow chart that may be used in some embodiments. A stack with a silicon containing layer and a mask over a substrate is received in a process chamber (step 104). FIG. 2A is a schematic cross-sectional view of a stack 200 used in an embodiment. In some embodiments, the stack comprises a substrate 208 under a plurality of bilayers 212, which is disposed below a carbon containing patterned mask 216. One or more layers may be disposed between the substrate 208 and the plurality of bilayers 212 or the plurality of bilayers 212 and the carbon containing patterned mask 216. The carbon containing patterned mask 216 may be amorphous carbon. In some embodiments, the patterned mask pattern provides mask features 220 for high aspect ratio contacts. In some embodiments, the mask features are formed before the substrate is placed in the etch chamber. In other embodiments, the mask features 220 are formed while the substrate is in the etch chamber. In some embodiments, the plurality of bilayers 212 are bilayers of a layer of silicon oxide 224 and a layer of silicon nitride 228. In some embodiments, the stack may comprise repeating sequences of 3 or more layers.

Features are etched into the stack 200 through the carbon containing mask 216 depositing a passivation layer on sidewalls of the features (step 108). In some embodiments, the etch step comprises providing an etch gas and forming a plasma from the etch gas, where the plasma etches features into the stack 200. In some embodiments, the etch gas comprises a halogen containing etchant, an inert bombardment gas, and a passivant. In some embodiments, the halogen containing etchant is a fluorine containing gas. In some embodiments, the bombardment gas comprises at least one of He, Ne, Ar, Kr, Xe, and N₂. In some embodiments, a substrate support is maintained at a temperature in a range of about −80° C. and 150° C. In some embodiments, a chamber pressure is maintained at a pressure of about 5 to 400 millitorr (mT). In some embodiments, the etch gas is transformed into a plasma. In some embodiments, a pulsed RF power is provided at different frequencies and power ranges. For example, during a first phase, RF power at 400 kilohertz (kHz) at a power in the range of 0-1500 watts (W) and RF power at 60 megahertz (MHz) at a power in the range of 0-1000 W may be provided. Different powers may be provided at each frequency component. The patterned mask layer protects the underlying stack materials at positions where the patterned mask layer is present. This ensures that the etched features are formed at the openings patterned into the mask layer, where the recessed features are desired. In order to etch the etch front for high aspect ratio features, in some embodiments, a bias power of greater than 10 kW is provided. In some embodiments, during the etching of the features, a substrate support for supporting the stack in an etch chamber is cooled to a temperature below 0° C. In some embodiments, the substrate support is cooled to a temperature below −10° C.

FIG. 2B is a cross-sectional view of the stack 200 after the contacts 232 have been etched. The contacts are high aspect ratio contacts. Preferably, the high aspect ratio contacts have a height to CD width ratio of greater than 40:1. More preferably, the contacts have an etch depth to feature CD width aspect ratio of greater than 100:1.

FIG. 2C illustrates an enlarged portion of FIG. 2B, as indicated, showing sidewalls of bilayers of a layer of silicon oxide 224 and a layer of silicon nitride 228 under a carbon containing mask 216. The sidewalls 240 are not vertical or smooth. For example, the sidewalls 240 have a mouse bite or scalloped roughness. Roughness may be defined as silicon oxide 224 layer to silicon nitride 228 layer roughness measured using an electron microscope. In some embodiments, the roughness of the sidewalls is in the range of 5 nm to 10 nm. In some embodiments, a passivation layer 244 is formed over the sidewalls 240. In some embodiments, the passivation layer 244 comprises a metal component.

An optional wet clean may be provided to remove the passivation layer (step 112). FIG. 2D illustrates the enlarged portion after the optional wet clean is provided. The passivation layer 244 (shown in FIG. 2C) has been removed. In some embodiments, metal containing contaminants 248 remain after the optional wet clean process. In some embodiments, the metal containing contaminants 248 may be embedded 1 to 2 nm into the sidewalls. Since the contaminants are electrically conductive, the contaminants can cause defects in the resulting semiconductor devices.

Next, a post etch plasma treatment to reduce sidewall roughness is provided (step 116). A treatment gas is provided. The treatment gas comprises a bombardment gas and may provide a concentration of a mask protection component that may be a passivant and a halogen that may be an etchant. The bombardment ions have enough energy to reduce the sidewall roughness and remove embedded contaminants but do not have enough energy to vertically etch the etch front. By reducing the sidewall roughness and removing contaminants the reliability of resulting semiconductor devices is improved and defects are reduced. In an example, a pretreatment process may provide 0-5% hydrofluorocarbon, 75-100% of neutral gas, and 0-20% NF₃, where percentages of gases are measured by volume. Pulsed RF power is provided at 60 MHz at a power of 1-3 kW and at 400 kHz at a power of 0-15 kW with a 20-60% duty cycle. The post etch plasma treatment is provided for a time of 1-200 seconds. Generally, in some embodiments, the etchant is less than 20% of the total treatment gas, the passivant is less than 5% of the total treatment gas, and the bombardment gas is greater than 75% of the total treatment gas measured by volume. In some embodiments, other low frequency bias RF may be provided instead of 400 kHz. Other high frequency excitation RF may be provided instead of 60 MHz. In some embodiments, the bias power is less than 15 kW.

FIG. 2E illustrates the enlarged portion after the post etch plasma treatment. The roughness of the sidewall 240 has been reduced. In addition, the metal containing contaminants 248, shown in FIG. 2D are removed. In some embodiments, the roughness of the sidewalls is less than 2 nm.

In some embodiments, an optional wet clean is provided (step 120) after the post etch plasma treatment (step 116). In some embodiments, the optional wet clean (step 120) after the post etch plasma treatment is provided without the optional wet clean (step 112) before the post etch plasma treatment. In some embodiments, both an optional wet clean (step 112) before the post etch plasma treatment and an optional wet clean (step 120) after the post etch plasma treatment are provided. In some embodiments, neither the optional wet clean (step 112) before the post etch plasma treatment nor the optional wet clean (step 120) after the post etch plasma treatment are provided.

By providing a post etch plasma treatment, sidewall smoothness and sidewall contaminant reduction do not need to be considered during the etch process. As a result, the etch recipe is tuned for etch selectivity, aspect ratio, prevention of twisting, CD uniformity, etch rate, and other possible features, such as circularity. Some etch processes form metal containing sidewall passivation or use a metal doped mask that form metal contaminants. Although a wet clean removes most of the metal contaminants, the post etch plasma treatment more completely removes metal contaminants in addition to reducing sidewall roughness.

Since the post etch plasma treatment is to remove contaminants and roughness on the sidewalls instead of etching at the etch front, the ion energy during the post etch plasma treatment is lower than the ion energy during the etch. As a result, the bias power and voltage during the post etch plasma treatment is lower than the bias power and voltage during the etch. During the etch a passivation layer is deposited on the sidewalls. During the post etch plasma treatment a passivation layer is not deposited. However, in some embodiments, the post etch plasma treatment may deposit a mask protection deposition. As a result, the treatment gas may be either free of a passivant or have a lower concentration of passivant than the concentration of passivant of the etch gas to provide mask protection. If the etch uses a metal containing passivant or another non-hydrocarbon passivant, in some embodiments, the treatment gas may be free of such non-hydrocarbon passivants. In some embodiments, the treatment gas is either free of or has a lower concentration of hydrocarbon passivants than the etch gas. Since the post etch plasma treatment relies on ion bombardment of the sidewalls to reduce roughness and remove contaminants instead of a combination of a halogen and ion bombardment to vertically etch the etch front, the treatment gas is free of or has a lower concentration of halogen than the etch gas. In some embodiments, the treatment gas has a low concentration of halogen, such as fluorine in order to prevent clogging of the features or capping of the mask. In some embodiments, the etchant is at least one of sulfur hexafluoride (SF₆) and nitrogen trifluoride (NF₃). In some embodiments, the bias and power, along with halogen concentrations, and mask protection may be tuned during the post etch plasma treatment to minimize surface roughness without increasing bowing or impacting pillar profile. In some embodiments, the post etch plasma treatment is performed in the same chamber as the etch. In some embodiments, the post etch plasma treatment is performed in a different chamber than the etch. Control of the ratio of inert bombardment gas to etchant gas allows enough etchant gas to prevent clogging or capping of the mask but not enough etchant gas to significantly etch the mask and/or cause sidewall damage. The etching the features provides an etch gas comprising a bombardment gas and an etchant with a bombardment gas to etchant ratio, wherein the bombardment gas to etchant ratio of the treatment gas is greater than the bombardment gas to etchant ratio of the etch gas. The treatment gas has a passivant to bombardment gas ratio. The etch gas has a passivant to bombardment gas ratio. In some embodiments, the ratio of the passivant to the bombardment gas of the treatment gas is less than the ratio of the passivant to the bombardment gas of the etch gas.

In some embodiments, there is more surface roughness near the tops of the etch features and very little surface roughness near the bottoms of the features. As a result, in some embodiments, post treatment ions only need enough energy and bias to reduce the surface roughness closer to the tops of the etch features. In some embodiments, the post treatment ions do not have sufficient energy to affect the bottoms of the etch features. Ion energy control allows ions with enough energy to reduce surface roughness near the tops of the etch features and an energy low enough to prevent damage to sidewalls of the etch features lower in the etch features in order to prevent bowing and also low enough to prevent mask sputtering. In some embodiments, RF pulsing is used to provide controlled bias power.

In some embodiments, control of the mask thickness at the time of the post etch plasma treatment is another parameter that may be used to control the depth of the reduction of surface roughness. A thinner mask and lower aspect ratio allow for the reduction of the surface roughness deeper into the etch features. A thicker mask and higher aspect ratio reduce the depth at which the surface roughness is reduced. The aspect ratio of the mask may be controlled by the concentration of etchant gas and resulting etchant species. A higher concentration of etchant gas increases the aspect ratio of mask features causing the surface roughness to be reduced deeper into the etch features.

In some embodiments, control of the length of time for the post etch plasma treatment may be used to control how much the surface roughness is reduced. A longer period for the post etch plasma treatment will reduce more surface roughness. However, if the period is too long the possibility of sidewall damage increases.

In some embodiments, since the post etch plasma treatment is separate from the etch process, the surface roughness can be tuned and can be completely removed without affecting the results of the etch process, so that additional tradeoffs are not needed during the etch process. In some embodiments, the post etch plasma treatment can be scaled up to a higher aspect ratio to meet the needs of future devices.

### Apparatus

The various hardware and method embodiments described above may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility.

Lithographic patterning of a film typically comprises some or all of the following steps, each step enabled with a number of possible tools: (1) application of photoresist on a workpiece, e.g., a substrate having a silicon containing film formed thereon, using a spin-on or spray-on tool; (2) curing of photoresist using a hot plate or furnace or other suitable curing tools; (3) exposing the photoresist to visible or ultraviolet (UV) or x-ray light with a tool such as a wafer stepper; (4) developing the resist so as to selectively remove resist and thereby pattern it using a tool such as a wet bench or a spray developer; (5) transferring the resist pattern into an underlying film or workpiece by using a dry or plasma-assisted etching tool; and (6) removing the resist using a tool such as an RF or microwave plasma resist stripper. In some embodiments, an ashable hard mask layer (such as an amorphous carbon layer) and another suitable hard mask (such as an antireflective layer) may be deposited prior to applying the photoresist.

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, 300 mm, or 450 mm. The above detailed description assumes the embodiments are implemented on a wafer. However, the embodiments are not so limited. The workpiece may be of various shapes, sizes, and materials. In addition to semiconductor wafers, other work pieces that may take advantage of the disclosed embodiments include various articles such as printed circuit boards, magnetic recording media, magnetic recording sensors, mirrors, optical elements, micro-mechanical devices, and the like.

Unless otherwise defined for a particular parameter, the terms “about” and “approximately” as used herein are intended to mean ±10% with respect to a relevant value.

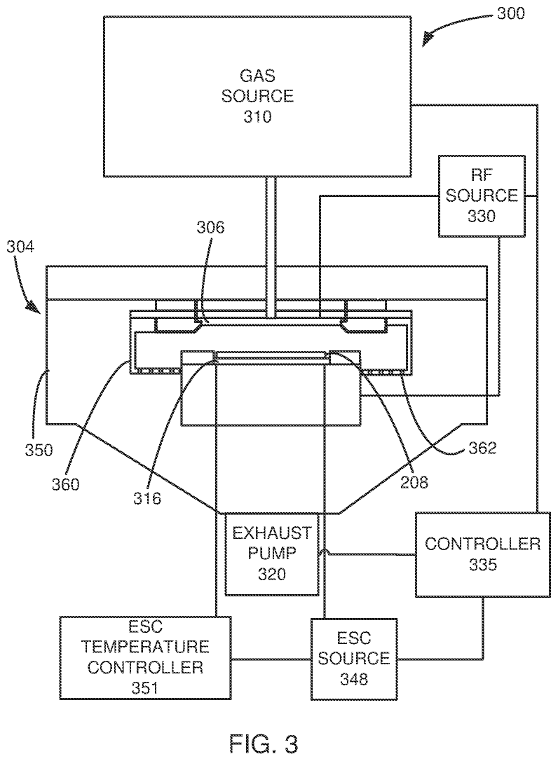

FIG. 3 is a schematic view of a plasma processing chamber 300 for plasma processing substrates, in an embodiment. In one or more embodiments, the plasma processing chamber 300 comprises a gas distribution plate 306 providing a gas inlet and an electrostatic chuck (ESC) 316, within a plasma processing chamber 304, enclosed by a chamber wall 350. Within the plasma processing chamber 304, the substrate 208 is positioned on top of the ESC 316. The ESC 316 may provide a bias from an ESC power source 348. A gas source 310 is connected to the plasma processing chamber 304 through the gas distribution plate 306. An ESC temperature controller 351 is connected to the ESC 316 and provides temperature control of the ESC 316. A radio frequency (RF) power source 330 provides RF power to the ESC 316 and an upper electrode. In this embodiment, the upper electrode is the gas distribution plate 306. In a preferred embodiment, 400 kilohertz (kHz), 13.56 megahertz (MHz), 1 MHZ, 2 MHz, 60 MHZ, and/or optionally, 27 MHz power sources make up the RF power source 330 and the ESC power source 348. A controller 335 is controllably connected to the RF power source 330, the ESC power source 348, an exhaust pump 320, and the gas source 310. A high flow liner 360 is a liner within the plasma processing chamber 304, which confines gas from the gas source and has slots 362. The slots 362 maintain a controlled flow of gas to pass from the gas source 310 to the exhaust pump 320. An example of such a plasma processing chamber is the Flex® etch system manufactured by Lam Research Corporation of Fremont, CA. The process chamber can be a CCP (capacitively coupled plasma) reactor or an ICP (inductively coupled plasma) reactor.

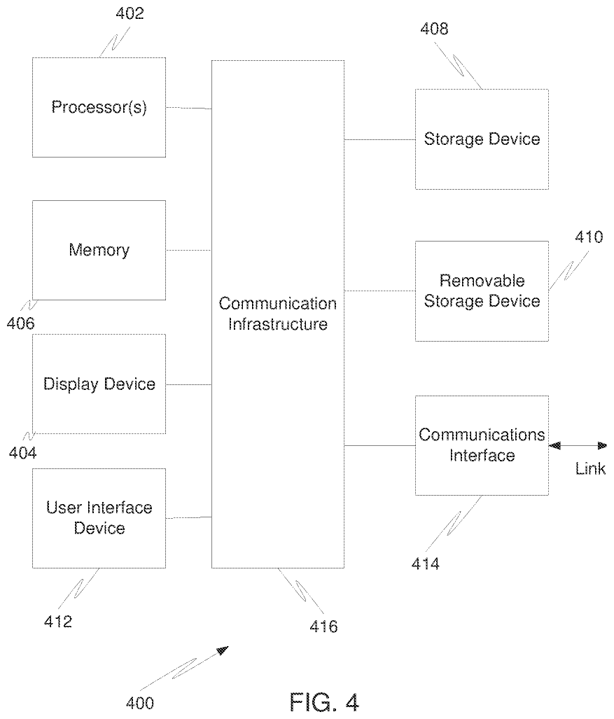

FIG. 4 is a high level block diagram illustrating a computer system 400 for implementing the controller 535 used in embodiments of the present inventions. The computer system may have many physical forms ranging from an integrated circuit, a printed circuit board, and a small handheld device up to a huge supercomputer. The computer system 400 may include one or more processors 402, and further can include an electronic display device 404 (for displaying graphics, text, and other data), a main memory 406 (e.g., random access memory (RAM)), storage device 408 (e.g., hard disk drive), removable storage device 410 (e.g., optical disk drive), user interface devices 412 (e.g., keyboards, touch screens, keypads, mice or other pointing devices, etc.), and/or a communication interface 414 (e.g., wireless network interface). The communication interface 414 may allow software and/or data to be transferred between the computer system 400 and external devices via a link. The system may also include a communications infrastructure 416 (e.g., a communications bus, cross-over bar, or network) to which the aforementioned devices/modules may be connected.

The information transferred via communications interface 414 may be in the form of signals such as electronic, electromagnetic, optical, or other signals capable of being received by communications interface 414, via a communication link that carries signals and may be implemented using wire or cable, fiber optics, a phone line, a cellular phone link, a radio frequency link, and/or other communication channels. With such a communications interface, it is contemplated that the one or more processors 402 might receive information from a network or might output information to the network in the course of performing the above-described method steps. Furthermore, method embodiments may execute solely upon the processors or may execute over a network such as the Internet in conjunction with remote processors that shares a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

It is to be understood that the configurations and/or approaches described herein are exemplary in nature and that these specific embodiments or examples are not to be considered in a limiting sense, because numerous variations are possible. The specific routines or methods described herein may represent one or more of any number of processing strategies. As such, various acts illustrated may be performed in the sequence illustrated, in other sequences, in parallel, or in some cases omitted. Likewise, the order of the above described processes may be changed. Certain references have been incorporated by reference herein. It is understood that any disclaimers or disavowals made in such references do not necessarily apply to the embodiments described herein. Similarly, any features described as necessary in such references may be omitted in the embodiments herein. The subject matter of the present disclosure includes all novel and nonobvious combinations and sub-combinations of the various processes, systems, configurations, and other features, functions, acts, and/or properties disclosed herein, as well as any and all equivalents thereof.

### CONCLUSION

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A method of forming features in stack with a silicon containing layer below a mask, the method comprising:
etching features into the stack; and
providing a post etch plasma treatment to reduce surface roughness of sidewalls of the features.

2. The method of claim 1, further comprising providing a wet clean of a passivation layer formed in the features by the etching the features.

3. The method of claim 2, wherein the providing the wet clean is before providing the post etch plasma treatment, wherein the providing the wet clean leaves contaminants in the features and wherein the providing the post etch plasma treatment removes the contaminants.

4. The method of claim 3, wherein the contaminants are metal containing contaminants.

5. The method of claim 2, wherein the providing the wet clean is after providing the post etch plasma treatment.

6. The method of claim 1, wherein the providing the post etch plasma treatment provides a bias power and the etching the features provides a bias power, wherein the bias power provided by the post etch plasma treatment is less than the bias power provided by the etching the features.

7. The method of claim 1, wherein the providing the post etch plasma treatment provides a treatment gas comprising a bombardment gas and an etchant with a bombardment gas to etchant ratio and wherein the etching the features provides an etch gas comprising a bombardment gas and an etchant with a bombardment gas to etchant ratio, wherein the bombardment gas to etchant ratio of the treatment gas is greater than the bombardment gas to etchant ratio of the etch gas.

8. The method of claim 1, wherein the providing the post etch plasma treatment provides a treatment gas comprising a bombardment gas and a passivant with a passivant to bombardment gas ratio and wherein the etching the features provides an etch gas comprising a bombardment gas and a passivant with a passivant to bombardment gas ratio, wherein a ratio of the passivant to bombardment gas of the treatment gas is less than a ratio of the passivant to bombardment gas of the etch gas.

9. The method, as recited in claim 7, wherein the bombardment gas comprises at least one of He, Ne, Ar, Kr, Xe, and N₂.

10. The method of claim 1, wherein the etching the features deposits metal contaminants in the features and wherein the providing the post etch plasma treatment removes metal contaminants.

11. The method, as recited in claim 1, wherein the mask is a carbon containing mask.

12. The method, as recited in claim 1, wherein the mask is amorphous carbon.

13. The method, as recited in claim 1, wherein the mask is a carbon containing mask and the stack comprises a plurality of alternating silicon oxide layers or silicon nitride layers.

14. The method, as recited in claim 1, wherein the mask is a carbon containing mask and wherein the stack includes a plurality of alternating silicon oxide and polysilicon layers.

15. The method, as recited in claim 1, wherein the features have a height to width ratio greater than 40:1.

16. The method, as recited in claim 1, wherein the mask is a carbon containing mask and wherein the stack comprises at least one layer of silicon oxide.

17. The method, as recited in claim 1, wherein the providing the post etch plasma treatment provides a treatment gas comprising a passivant wherein the passivant is no more than 5% of the total treatment gas.

18. The method, as recited in claim 1, wherein the providing the post etch plasma treatment provides a treatment gas comprising an etchant wherein the etchant is no more than 20% of the total treatment gas.

19. The method, as recited in claim 1, wherein the providing the post etch plasma treatment provides a treatment gas comprising bombardment gas wherein the bombardment gas is at least 75% of the total treatment gas.
